(19) United States
(12) Patent Application Publication
(10) Pub. No.: US 2015/0187664 A1
(43) Pub. Date: Jul. 2, 2015

(54) High Productivity Combinatorial Testing of Multiple Work Function Materials on the Same Semiconductor Substrate

(71) Applicant: Intermolecular Inc., San Jose, CA (US)

(72) Inventor: Amol Joshi, Sunnyvale, CA (US)

(73) Assignee: Intermolecular Inc., San Jose, CA (US)

(21) Appl. No.: 14/140,727

(22) Filed: Dec. 26, 2013

(51) Int. Cl. H01L 21/66; H01L 21/28

(52) U.S. Cl. CPC H01L 22/14; H01L 21/28158

(57) ABSTRACT

Provided are methods of high productivity combinatorial (HPC) screening of work function materials. Multiple test materials may be deposited as separate blanket layers on the same substrate while still forming individual interfaces with a common base layer. The thickness of each test material layer ensures that its work function properties are not impacted when other layers are deposited over that layer. A method may involve depositing a blocking layer over the base layer and selectively removing the blocking layer from a first site isolated region. A first test material is then deposited as a blanket layer and forms an interface with the base layer in that first region only. The first test material layer and the blocking layer are selectively removed from a second site isolated region followed by depositing a second test material layer as another blanket layer, which forms an interface with the base layer in the second region only.

### BACKGROUND

Work function materials are gaining widespread applications in various semiconductor devices. Prior to introducing a new work function material or a new deposition process, the material and/or the process needs to be thoroughly tested and compared to other materials and deposition processes. Yet, work function materials are typically deposited as blanket films using, for example, an atomic layer deposition (ALD) technique, a chemical vapor deposition (CVD) technique, and/or a physical vapor deposition (PVD) technique. These deposition techniques conventionally yield only one test sample per substrate, i.e., a blanket layer covering all or part of the substrate. Some approaches have been recently proposed to limit deposition areas on a substrate thereby allowing deposition of multiple test samples on the same substrate. However, these limited-area deposition approaches require complex equipment and tend to be slow and expensive. As such, comprehensive testing of work function materials remains difficult and expensive.

### SUMMARY

Provided are methods of high productivity combinatorial (HPC) testing of work function properties. Multiple test materials may be deposited as separate blanket layers on the same substrate while still forming individual interfaces with a common base layer. The thickness of each test material layer ensures that its work function properties are not impacted when other layers are deposited over that layer. A method may involve depositing a blocking layer over the base layer and selectively removing the blocking layer from a first site isolated region. A first test material is then deposited as a blanket layer and forms an interface with the base layer in that first region only. The first test material layer and the blocking layer are selectively removed from a second site isolated region followed by depositing a second test material layer as another blanket layer, which forms an interface with the base layer in the second region only.

In some embodiments, a method of HPC testing of multiple work function materials on a semiconductor substrate involves providing the semiconductor substrate including a first layer, which may be also referred to as a base layer. The substrate may have multiple site isolated regions. The method proceeds with depositing a second layer on the semiconductor substrate over the first layer. The second layer may be also referred to as a blocking layer. The method then proceeds with selectively removing a first portion of the second layer in a first site isolated region of the multiple site isolated regions thereby creating a first exposed portion of the first layer and depositing a first test layer over the second layer and the first exposed portion of the first layer. The first test layer includes a first work function material. The method proceeds with selectively removing a second portion of the second layer and a first portion of the first test layer in a second site isolated region of the multiple site isolated regions thereby creating a second exposed portion of the first layer. A second test layer is then deposited over the first test layer and the second exposed portion of the first layer. The method proceeds with measuring one or more work function properties of the first site isolated region and the second site isolated region of the substrate.

In some embodiments, the first layer includes a dielectric material such as silicon oxide, aluminum oxide, hafnium oxide, or zirconium oxide. The second layer may include one of silicon, titanium nitride, or silicon oxide. The first layer may remain substantially intact when selectively removing the first portion of the second layer in the first site isolated region and when selectively removing the portion of the second layer and the portion of the first test layer in the second site isolated region. In some embodiments, selectively removing the portion of the second layer and the portion of the first test layer in the second site isolated region involves selectively removing the portion of the second layer using a first set of process conditions and selectively removing the portion of the first test layer using a second set of process conditions different from the first set of process conditions. Selectively removing the portion of the first test layer may involve contacting the first layer in the second site isolated region with a first etching solution thereby forming an exposed portion of the second layer. Selectively removing the portion of the second layer involves contacting the exposed portion of the second layer with a second etching solution. The second etching solution may have a different composition than the first etching solution. In some embodiments, the first layer is not resistant to the first etching solution.

In some embodiments, selectively removing the portion of the second layer and the portion of the first test layer in the second site isolated region is performed in one operation using a same set of process conditions. For example, selectively removing the portion of the second layer and the portion of the first test layer in the second site isolated region involves contacting the first test layer and the second layer with an etching solution. In some embodiments, the first layer is resistant to the etching solution.

Selectively removing the portion of the second layer and the portion of the first test layer in the second site isolated region may be performed by contacting the second site isolated region with one or more etching solutions such that a remaining portion of the semiconductor substrate outside of the second site isolated region does not come in contact with the one or more etching solutions. For example, each site isolated region may be isolated with a seal.

In some embodiments, prior to measuring, the method may also involve selectively removing a third portion of the second layer, a second portion of the first test layer, and a first portion of the second test layer in a third site isolated region of the multiple site isolated regions thereby creating a third exposed portion of the first layer. The method may then proceed with depositing a third test layer over the second test layer and the third exposed portion of the first layer.

In some embodiments, depositing the first test layer and the second layer comprises one or more of an atomic layer deposition (ALD) technique, a chemical vapor deposition (CVD) technique, or a physical vapor deposition (PVD) technique. In some embodiments, the first test layer is deposited using a different technique than the second test layer. In some embodiments, the first test layer and the second test layer may have the same composition. In some embodiments, the first test layer is deposited using a CVD technique and the second test layer is deposited using an ALD technique.

The second test layer is generally deposited over the first test layer in the first site isolated region. The thickness of each of the first test layer and the second test layer is between about 1 nanometer and 20 nanometers. In some embodiments, measuring one or more work function properties of the first site isolated region and the second site isolated region of the substrate involves one of a capacitance test, a resistance test, or a transistor test. In some embodiments, one or more of the work function properties of the first site isolated region are not impacted by presence of the second layer in the first site isolated region.

These and other embodiments are described further below with reference to the figures.

### BRIEF DESCRIPTION OF THE DRAWINGS

FIG. 1 illustrates a schematic diagram for implementing combinatorial processing and evaluation using primary, secondary, and tertiary screening, in accordance with some embodiments.

FIG. 2 is a simplified schematic diagram illustrating a methodology for combinatorial process sequence integration that includes site isolated processing and/or conventional processing, in accordance with some embodiments.

FIG. 3 illustrates a schematic diagram of a substrate that has been processed in a combinatorial manner, in accordance with some embodiments.

FIG. 4 illustrates a schematic diagram of a combinatorial wet processing system, in accordance with some embodiments.

FIG. 5 is a process flowchart corresponding to a method of high productivity combinatorial (HPC) testing of multiple work function materials on the same semiconductor substrate, in accordance with some embodiments.

FIG. 6A-6F are schematic views of a substrate portion during various stages of testing multiple work function materials on the substrate or, more specifically, forming multiple test samples on the substrate, in accordance with some embodiments.

### DETAILED DESCRIPTION

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

### Introduction

Some approaches have been recently proposed for comprehensive testing of work function materials. Although these approaches describe deposition of multiple test work function materials on the same substrate, techniques for comparing work function materials deposited on the same substrate using different methods, e.g., ALD and CVD, are generally not described in these approaches. Furthermore, results obtained according to these approaches and based on the CVD method may not be extendable to the ALD method and vice versa.

This disclosure relates to techniques for combinatorial evaluation of semiconductor processing techniques. Provided are methods for HPC testing of work function properties of multiple materials on the same substrate. The ALD and CVD methods are traditionally full area (i.e., blanket film) deposition methods. The full area deposition methods generally do not allow for spot by spot HPC deposition of different, or differently-processed, ALD and CVD work function test materials on isolated regions of the same substrate without making significant hardware modifications and providing process control for restricting deposition on specific areas. The disclosed methods allow HPC testing of the ALD and CVD work function test materials side by side on the same substrate. Multiple test materials may be deposited as blanket layers on the same substrate while forming individual interfaces with a common base layer of the substrate. The thickness of each test material layer ensures that its work function properties are not impacted by other layers formed on top of the test material layer. Specifically, each test layer interfacing the base layer has a certain minimum thickness such that any other layer deposited of this test layer does not impact the work function characteristics of the test layer at this interface. In general, any number of additional layers may be formed over the test layer without impacting the work function characteristics.

The method may involve depositing a blocking layer over the base layer and selectively removing the blocking layer from a first site isolated region. Addition of the blocking layer prior to deposition of a blanket layer of a work function test material (i.e., a test layer) helps to eliminate contact between the test layer and the base layer in any area other than the first site isolated region. As such, the test layer will affect measurements within the first site isolation region only. This feature allows effective HPC deposition using simple blanket deposition combined with wet etching, rather than using complex spot-deposition techniques. In particular, two or more work function test materials may be compared side by side on the same substrate but in different site isolated regions. The method may further involve depositing a first test material as a blanket layer. Removal of the blocking layer only from the first isolated region allows the first test material to form an interface with the base layer only in the first site isolated region. In all other areas, the first test material is separated from the base layer by the blocking layer.

When a second test material needs to be tested, the first test material layer and the blocking layer may be selectively removed from a second site isolated region. After the removal, the second test material layer may be deposited as another blanket layer. Because the blocking layer and the first test material layer are removed from the second site isolated region, this new blanket layer can only form an interface with the base layer in this second site isolated region. In all other areas, the second test material is separated from the base layer by at least the first test material or a combination of the first test material and the blocking layer. In fact, the second test material is separated from the base layer by the first test material alone only in the first site isolated region. Because the thickness of the first test material is above the saturation thickness in this first site isolated region, the second test material does not interfere with the work function characteristics of the first test material in this region. In all other areas of the substrate (i.e., areas excluding the first site isolated region and the second site isolated region), the second test material is separated from the base layer by the combination of the first test material and the blocking layer. Other materials may be tested in these other areas.

The method may continue for any number of test materials. Before deposition of another test material layer, the blocking layer and all test material layers over the blocking layer may be removed in a selected site isolated region. Thereafter, a desired test material layer may be deposited on the previous test material layer and the site isolated region where the blocking layer and all test material layers are removed. Therefore, the desired test material layer may form an interface with the base layer only in the site isolated region where the blocking layer and all test material layers are removed.

### High Productivity Combinatorial (HPC) Examples

HPC generally refers to techniques of differentially processing multiple regions of a substrate. It may involve varying materials, unit processes, process sequences, and other process parameters across multiple regions (referred to as site isolated regions) provided on the substrate. The varied materials, unit processes, or process sequences can be evaluated (e.g., characterized) to determine whether further evaluation is warranted or whether a particular solution is suitable for production or high volume manufacturing.

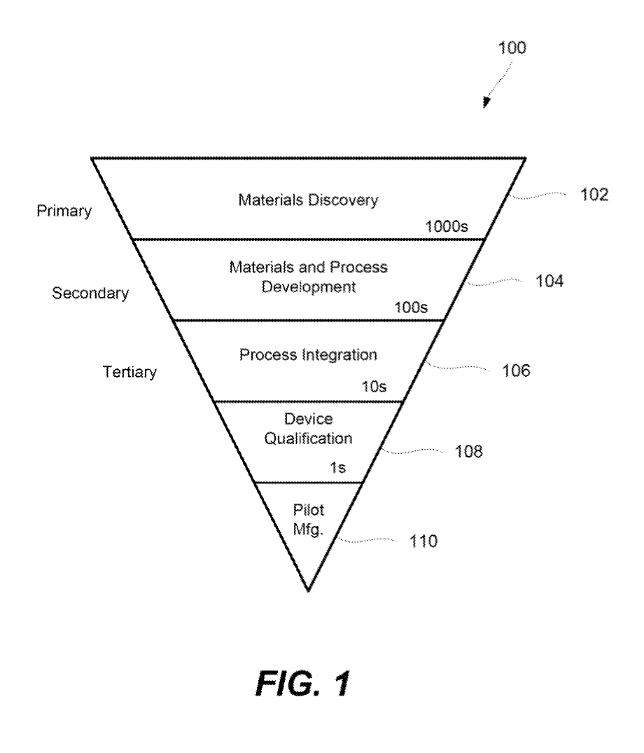

FIG. 1 illustrates a schematic diagram for implementing combinatorial processing and evaluation using primary, secondary, and tertiary screening, in accordance with some embodiments. Specifically, diagram 100 illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage 102. Materials discovery stage 102 is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage 104. Evaluation of the materials is performed using metrology tools such as electronic testers and imaging tools (i.e., microscopes).

Materials and process development stage 104 may evaluate hundreds of materials (i.e., a magnitude smaller than the primary stage) and may focus on the processes used to deposit or develop those materials. Promising materials and processes are again selected, and advanced to the tertiary screen or process integration stage 106, where tens of materials and/or processes and combinations are evaluated. Tertiary screen or process integration stage 106 may focus on integrating the selected processes and materials with other processes and materials.

The most promising materials and processes from the tertiary screen are advanced to device qualification 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing 110.

Diagram 100 is an example of various techniques that may be used to evaluate and select materials and processes for the development of new materials and processes. The descriptions of primary, secondary, etc. screening and the various stages 102-110 are arbitrary and the stages may overlap, occur out of sequence, be described and be performed in many other ways. Additional aspects of High Productivity Combinatorial (HPC) techniques are described in U.S. patent application Ser. No. 11/674,137, filed on Feb. 12, 2007, which is hereby incorporated by reference in its entirety for purposed of describing HPC techniques.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

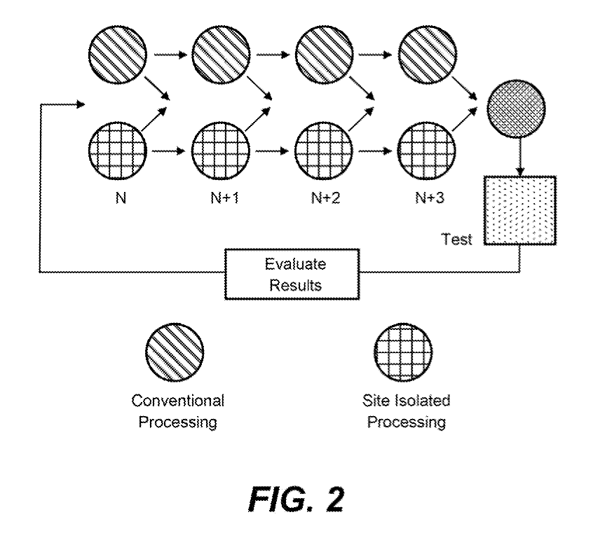

FIG. 2 is a simplified schematic diagram illustrating a general methodology for combinatorial process sequence integration that includes site isolated processing and/or conventional processing, in accordance to some embodiments. The substrate may be initially processed using conventional process N. In some embodiments, the substrate is then processed using site isolated process N+1. During site isolated processing, an HPC module may be used, some examples of which are described below. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor manufacturing may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

Combinatorial processing can be used to produce and evaluate different materials, chemicals, processes, process and integration sequences, and techniques related to semiconductor fabrication. For example, combinatorial processing can be used to determine optimal processing parameters (e.g., power, time, reactant flow rates, temperature, etc.) of dry processing techniques such as dry etching (e.g., plasma etching, flux-based etching, reactive ion etching (RIE)) and dry deposition techniques (e.g., physical vapor deposition (PVD), chemical vapor deposition (CVD), atomic layer deposition (ALD), etc.). Combinatorial processing can be used to determine optimal processing parameters (e.g., time, concentration, temperature, stirring rate, etc.) of wet processing techniques such as wet etching, wet cleaning, rinsing, and wet deposition techniques (e.g., electroplating, electroless deposition, chemical bath deposition, etc.).

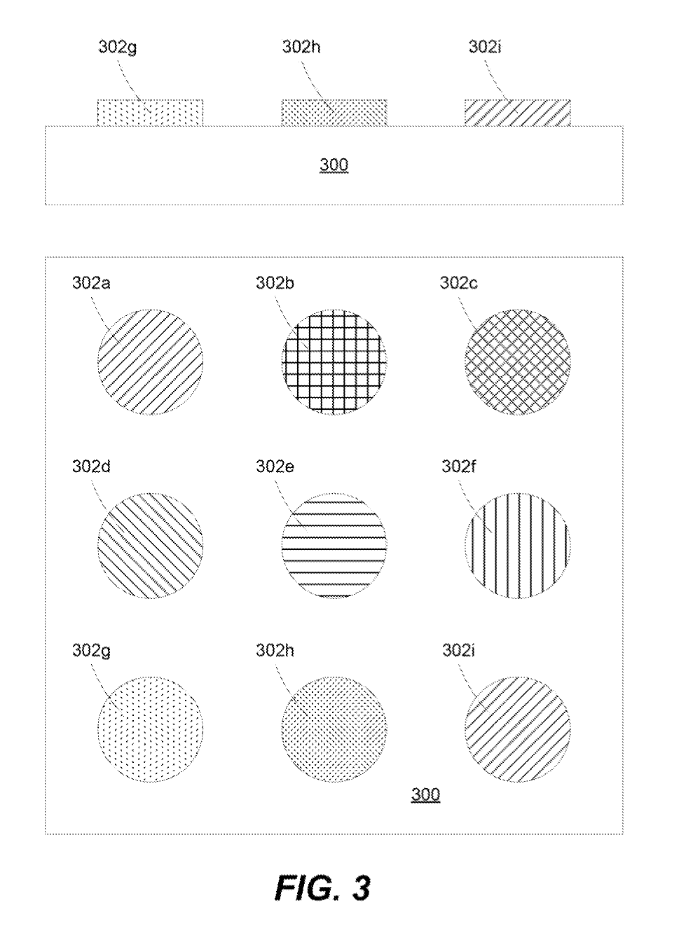

FIG. 3 illustrates a schematic diagram of a substrate 300 processed in a combinatorial manner, in accordance with some embodiments. Substrate 300 is shown to have nine site isolated regions 302a-302i. Although substrate 300 is illustrated as being a generally square shape, those skilled in the art will understand that the substrate may be any useful shape such as round, rectangular, etc. The lower portion of FIG. 3 illustrates a top down view while the upper portion of FIG. 3 illustrates a cross-sectional view taken through the three site isolated regions 302g-302i. The shading of the nine site isolated regions illustrates that the process parameters used to process these regions have been varied in a combinatorial manner. The substrate may then be processed through a next step that may be conventional or may also be a combinatorial step as discussed earlier with respect to FIG. 2. One having ordinary skills in the art would understand that the substrate may include any number of the site isolated regions, e.g., between about 20 and 40 or, more specifically, 28. All site isolated regions may be processed using different processing conditions. In some embodiments, two or more site isolated regions may be processed using the same processing conditions. For purposes of this disclosure, processing conditions are defined as any parameter that may impact on the outcome of the process. For example, in the etching context, processing parameters may include parameters of the etched materials (e.g., geometry, composition), composition of etching solution, processing temperature, duration, pre- and post-etching operations, and the like.

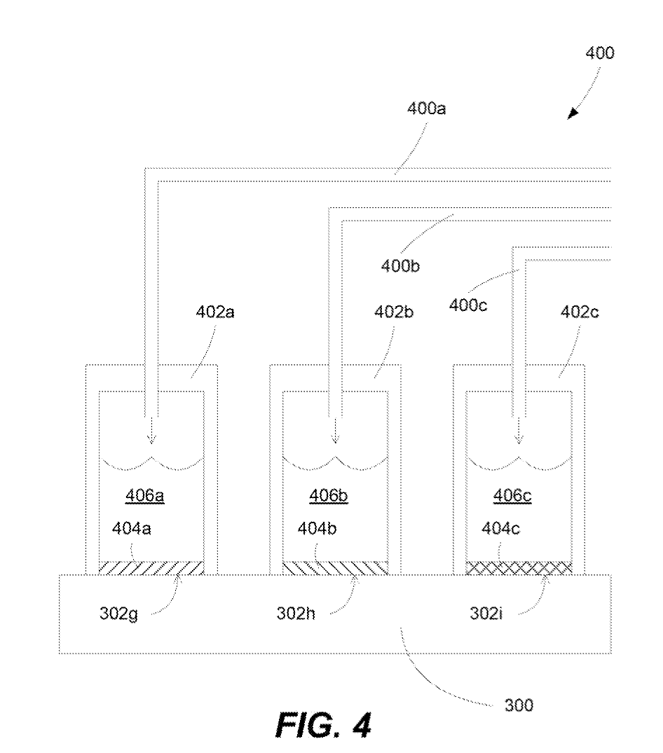

FIG. 4 illustrates a schematic diagram of a combinatorial wet processing system 400, in accordance with some embodiments. System 400 may be used to investigate materials deposited or, more generally, processed using solution-based techniques. Those skilled in the art would understand that this is only one possible configuration of a combinatorial wet system. FIG. 4 illustrates a cross-sectional view of substrate 300 taken through the three site isolated regions 302g-302i similar to the upper portion of FIG. 3 described above. Solution dispensing nozzles 400a-400c supply solutions 406a-406c having the same or different compositions (i.e., different solution chemistries 406a-406c) to chemical processing cells 402a-402c. FIG. 4 illustrates the deposition of layers 404a-404c within respective site isolated regions 302g-302i. Although FIG. 4 illustrates a deposition step, other solution-based processes such as cleaning, etching, surface treatment, surface functionalization, and the like may be investigated in a combinatorial manner. The solution-based treatment can be customized for each of the site isolated regions.

### HPC Testing Examples

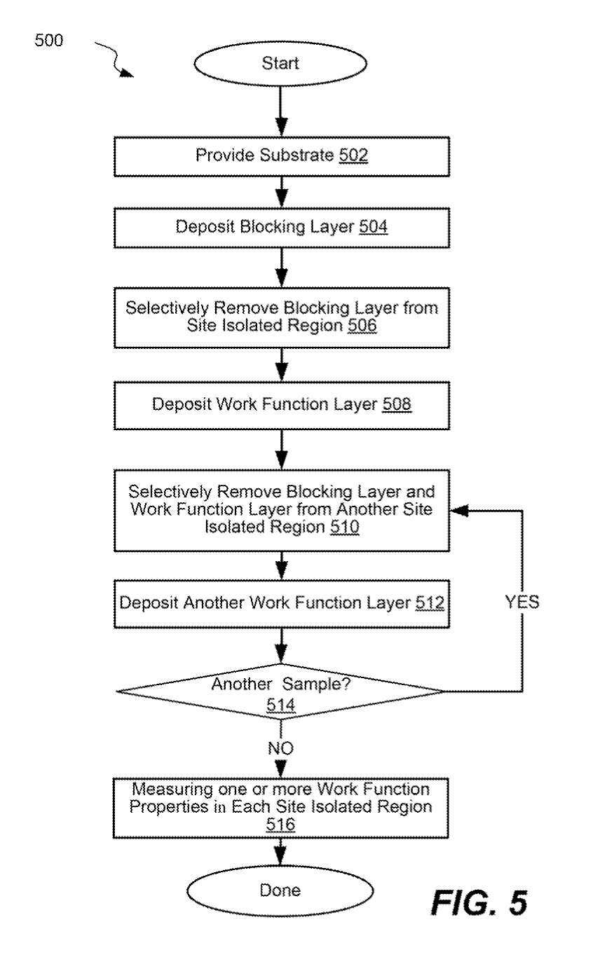

FIG. 5 is a process flowchart corresponding to a method 500 of HPC testing of multiple work function materials disposed on the same semiconductor substrate, in accordance with some embodiments. Method 500 may commence with providing the semiconductor substrate in operation 502. The semiconductor substrate may include a base layer, which may be formed from a dielectric material. In an example embodiment, the dielectric material includes silicon oxide (SiO₂), aluminum oxide (Al₂O₃), hafnium oxide (HfO₂), zirconium oxide (ZrO₂), and so forth. Although specific materials are illustrated for the base layer, those skilled in the art will understand that any suitable dielectric material may be selected for the base layer. For example, if the work-function metals are being evaluated for use in a metal gate stack for logic applications, the base layer can be a candidate gate-dielectric material.

Method 500 may proceed with depositing a blocking layer on the semiconductor substrate over the base layer in operation 504. In the example embodiment, the blocking layer includes silicon (Si), titanium nitride (TiN), silicon nitride (SiN), tantalum nitride (TaN), silicon oxide (SiO₂), tungsten (W), or other suitable materials. The blocking layer may be deposited using an atomic layer deposition (ALD) technique, a chemical vapor deposition (CVD) technique, a physical vapor deposition (PVD), or any other suitable technique. The blocking layer may be deposited as a blanket layer and cover the entire surface of the substrate or, more specifically, to cover the entire base layer. In some embodiments, the thickness of the blocking layer may be between about 5 nanometers and 1000 nanometers or, more specifically, between about between about 10 nanometers and 50 nanometers.

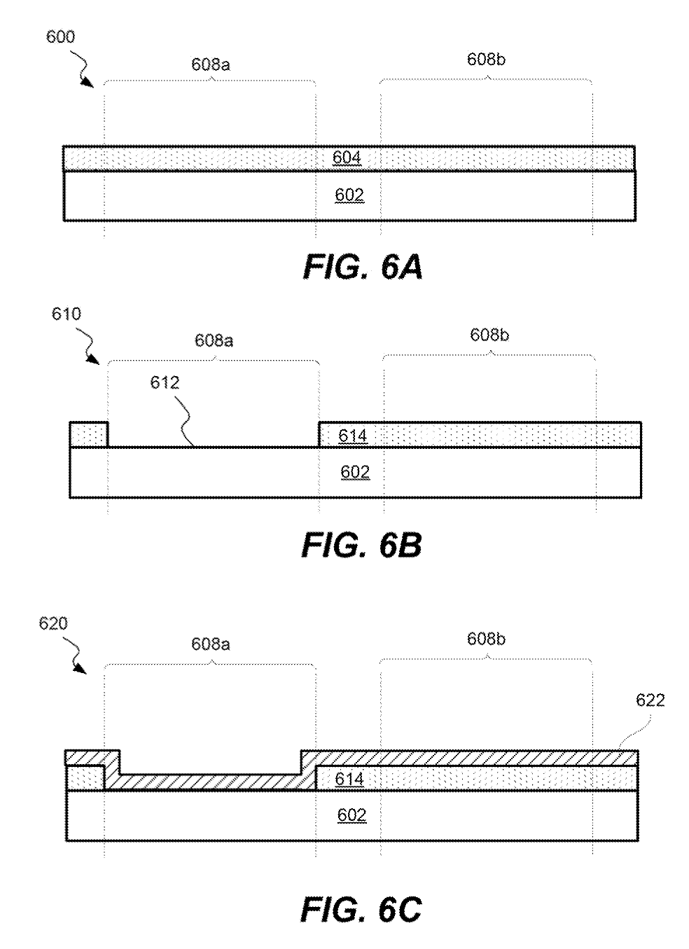

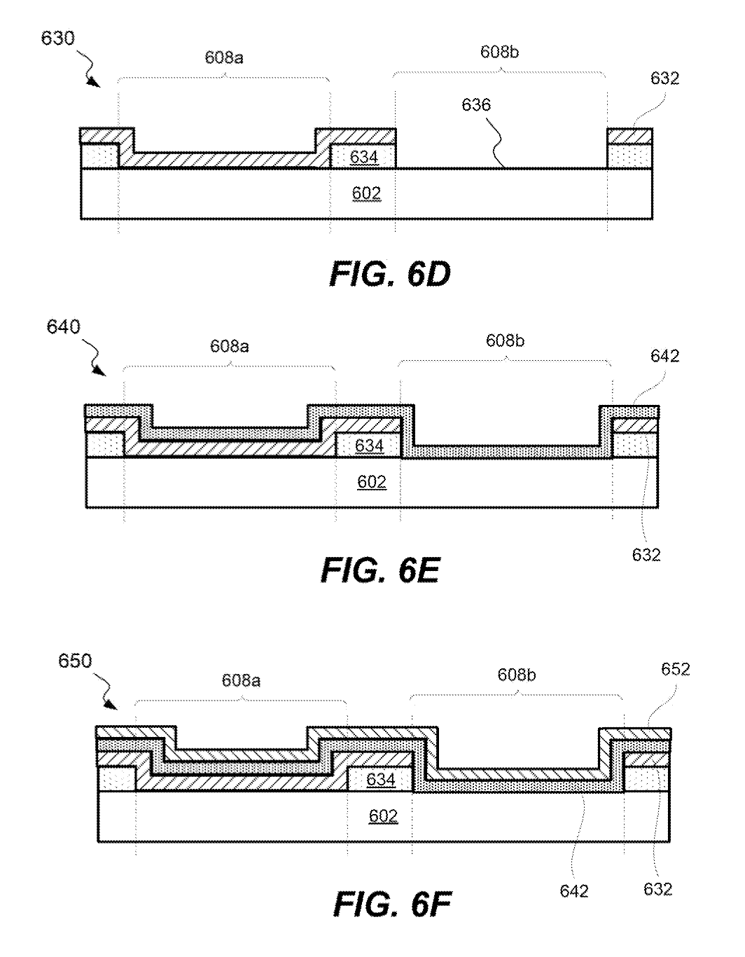

FIG. 6A illustrates a substrate portion 600 that includes blocking layer 604 deposited over base layer 602. At this stage, blocking layer 604 may temporarily cover base layer 602 and prevent base layer 602 from contacting a test layer, when it is later deposited on the substrate. In later operations, blocking layer 604 may be selectively etched without affecting base layer 602. Furthermore, blocking layer 604 may prevent a diffusion of test layer materials into base layer 602 during processing and measuring one or more work function properties (e.g., when substrate portion 600 is heated for deposition of test materials). At this stage, blocking layer 604 covers all site isolated regions on the substrate, such as first site isolated region 608a and second site isolated region 608b.

Returning to FIG. 5, after deposition of the blocking layer, method 500 may proceed with selectively removing a first portion of the blocking layer in a first site isolated region in operation 506. The first portion of the blocking layer may be selectively removed by etching using a specific set of process conditions. Specifically, the process conditions, such as etchant composition, etching duration, etching temperature, and so forth, may be specifically selected according to properties of the blocking layer. Furthermore, the optimal etching conditions may be different for layers grown by different techniques (e.g., atomic layer deposition versus physical vapor deposition). The process conditions may be selected in such a way that the blocking layer is removed in the first site isolated region without damaging the underlying base layer. For example, tetramethylammonium hydroxide (TMAH) may be used for etching silicon structures, and a dilute hydrofluoric acid (HF) may be used for etching silicon oxide structures.

In some embodiments, operation 506 may involve sealing the surface of the blocking layer along the perimeter of the first site isolated region. For example, a processing cell (elements 402a-402c shown in FIG. 4) may be sealed against that surface. The sealed portion of the blocking layer then gets exposed to a specifically formulated etching solution. The rest of the blocking layer is not in contact with this etching solution due to the seal. As such, etching of the blocking layer is limited to the first site isolated region. Processing individual site isolated regions is a part of the HPC methodology as reflected above.

FIG. 6B illustrates a substrate portion 610 in which the first portion of blocking layer 614 is removed from first site isolated region 608a. It should be noted that blocking layer 614 remains in second site isolated region 608b. As a result of this selective removal of the first portion of blocking layer 614 in first site isolated region 608a, a first exposed portion 612 of base layer 602 may be created in operation 506. In an example embodiment, base layer 602 remains substantially intact in the course of selective removal of the first portion of the blocking layer in first site isolated region 608a. For this purpose, the process conditions for etching the first portion of the blocking layer may be selected so that the base layer is resistant to the etching.

Returning to FIG. 5, after creating of the first exposed portion of the base layer during operation 506, method 500 may proceed with depositing a first test layer over the blocking layer and the first exposed portion of the base layer in operation 508. The first test layer may include a first work function material. The work function material of the first test layer and all subsequent test layers may include hafnium (Hf), zirconium (Zr), titanium (Ti), tantalum (Ta), aluminum (Al), tungsten (W), their alloys, their compounds (e.g., silicides, germanides, and nitrides), and the like. The first test layer may be deposited by one of the deposition techniques mentioned above, such as ALD, CVD, PVD, and so forth. The first test layer is deposited as a blanket layer over the substrate. Yet, the first test layer only interfaces the base layer in the first site isolated region. In all other parts of the substrate, the first test layer is separated from the base layer by the remaining portion of the blocking layer as, for example, shown in FIG. 6C.

Process conditions used for depositing the first test layer may be the same as used in production. In fact, actual production equipment may be used for depositing the first test layer, thereby forming a representative test sample. One having ordinary skills in the art would understand specific aspects of depositing the first test layer.

FIG. 6C illustrates a substrate portion 620 in which a first test layer 622, which is sometimes referred to as a first work function material layer, is deposited over blocking layer 614 and the first exposed portion of the base layer 602. The thickness of first test layer 622 may be between about 1 nanometer and 20 nanometers. This thickness is greater than the saturation thickness of the first test layer. Below this saturation thickness, the work function properties of the first test layer would be affected by layers above it, which may not be desirable if individual test layers are to be independently characterized. The saturation thickness is a function of the material for the first test layer. For example, it has been found that in a stack including titanium and platinum layers deposited over a platinum base layer, the bottom layer, which may be formed from either platinum or titanium, determines the work properties of the stack, when the thickness of this bottom layer exceeds 5 nanometers. This saturation thickness is applicable to both titanium layers and platinum layers. For example, the saturation thickness of titanium nitride is about 5 nanometers.

Overall, the thickness of each test layer that comes in contact with the base layer is important for further testing of this layer if additional layers are deposited over it. As noted above, it has been found that at a certain thickness, the bottom layer of a stack of multiple test layers starts dominating the work function properties of the stack. The thickness of a test layer, at which the test layer starts dominating work function properties of a stack, is referred herein to as a saturation thickness. Beyond this saturation thickness, the work function of the bottom layer is not sensitive to overlying layers. This phenomenon allows testing of properties of a specific material while other layers are formed over it.

Furthermore, the thickness of the first test layer may be significantly smaller than a size (e.g., a diameter) of the first site isolated region. In particular, the diameter of the first site isolated region may be in a millimeter-scale, while the thickness of the first test layer may be in a nanometer-scale. The first test layer may conformally cover the blocking layer and the base layer in the first site isolated region, as shown in region 608a in FIG. 6C. In other words, the thickness of the first test layer may be uniform over both the blocking layer and the base layer in the first site isolated region at about 1 nanometer to 20 nanometers. All further test layers described below may have the same thickness.

Returning to FIG. 5, after depositing the first test layer over the blocking layer and the first exposed portion of the base layer, method 500 may proceed with selectively removing a second portion of the blocking layer and a first portion of the first test layer in a second site isolated region in operation 510. By removal of the second portion of the blocking layer and a first portion of the first test layer, a second exposed portion of the base layer may be created.

FIG. 6D illustrates a substrate portion 630 having a second portion of blocking layer 634 removed, and also having a first portion of first test layer 622 removed to form etched first test layer 632. Both portions are removed in the second site isolated region 608b. It should be noted that the base layer may remain substantially intact in the course of this operation. An exposed portion 636 of base layer 602 is created in second site isolated region 608b. This exposed portion 636 is later used to form an interface with another test material as further described below.

Different layers may be etched using different etching conditions. The selective removal of the portion of the blocking layer and the portion of the first test layer in the second site isolated region may include selective removal of the portion of the first test layer using a first set of process conditions and then selective removal of the portion of the blocking layer using a second set of process conditions. The second set of process conditions may differ from the first set of process conditions. Specifically, the selective removal of the portion of the first test layer may include contacting the first test layer in the second site isolated region with a first etching solution. As a result, an exposed portion of the blocking layer may be formed. Similarly, the selective removal of the portion of the blocking layer may include contacting the exposed portion of the blocking layer with a second etching solution. The second etching solution may have a different composition than the first etching solution. These different process conditions may be provided by specific configurations of the processing equipment as described above with reference to FIG. 4. The contacting of the second site isolated region with one or more etching solutions during the selective removal of the portion of the blocking layer and the portion of the first test layer in the second site isolated region may be performed such that a remaining portion of the semiconductor substrate outside of the second site isolated region does not come in contact with the one or more etching solutions.

In an example embodiment, the base layer is non-resistant to the first etching solution used to remove a portion of the first test layer in the second site isolated region. For purposes of this document, a layer is deemed resistant to an etching solution if substantially no material (e.g., less than 5% of the initial thickness or even less than 1% of the initial thickness) is removed from this layer when the layer is exposed to an etching solution when exposed to the etching solution for between about 10 seconds and 30 minutes, such as for about 1 minute. Furthermore, the resistant layer preserves its structure and properties while being treated with an etchant. On other hand, a layer is deemed non-resistant to an etching solution if a substantially amount of material (e.g., greater than about 5% of the initial thickness or even greater than about 10% of the initial thickness) is removed from this layer when the layer is exposed to an etching solution when exposed to the etching solution for between about 10 seconds and 30 minutes, such as for about 1 minute. The non-resistant layer changes its structure and properties while being treated with an etchant. Returning to the above example, even though the base layer may be non-resistant to the first etching solution, the first etching solution does not permeate the blocking layer sufficiently to affect the base layer. It is blocked by the blocking layer while the first test layer is removed from the second site isolated region. However, when the blocking layer is removed from this second site isolated region using another etchant, the base layer needs to be resistant to this other etchant.

Alternatively, the selective removal of the portion of the blocking layer and the portion of the first test layer in the second site isolated region may be performed in a single operation using the same set of process conditions. Specifically, the portion of the blocking layer and the portion of the first test layer in the second site isolated region may be etched using the same set of process conditions. In this case, the selective removal of the portion of the blocking layer and the portion of the first test layer in the second site isolated region may include contacting the first test layer and the blocking layer with an etching solution. In particular, the portion of the blocking layer and the portion of the first test layer may be etched in a single unit process using one cell containing an etching solution. In this specific embodiment, the base layer is resistant to the etching solution used for etching of the portion of the blocking layer and the portion of the first test layer.

Returning to FIG. 5, after selective removal of the second portion of the blocking layer and the first portion of the first test layer in the second site isolated region, method 500 may proceed with depositing a second test layer over the first test layer and the second exposed portion of the base layer in operation 512. A thickness of the second test layer may be between about 1 nanometer and 20 nanometers, but may exceed the saturation thickness for the material being deposited. The second test layer may include a second work function material. As noted above, the work function material of this layer may include hafnium (Hf), zirconium (Zr), titanium (Ti), tantalum (Ta), aluminum (Al), tungsten (W), their alloys, their compounds (e.g., silicides, germanides, and nitrides) and the like. The second test layer may be deposited by the deposition techniques mentioned above, such as ALD, CVD, PVD, and so forth. The second test layer is deposited as a blanket layer over the substrate. Yet, the second test layer only interfaces the base layer in the second site isolated region. In all other parts of the substrate, the second test layer is separated from the base layer by the remaining portion of the blocking layer and the portions of the first layer as, for example, shown in FIG. 6E.

Specifically, FIG. 6E illustrates a substrate portion 640 in which second test layer 642 is deposited over previously etched first test layer 632 and the second exposed portion of base layer 602. First test layer 632 may be referred to as a first work function material layer, while second test layer 642 may be referred to as a second work function material layer.

As shown in FIG. 6E, second test layer 642 may only interface with base layer 602 in second site isolated region 608b. Second test layer 642 is deposited over first test layer 632 in first site isolated region 608a. Even though now first site isolated region 608a has a stack of two test layers, the work function properties of this stack will only reflect the work function properties of first test layer 632. The overlying presence of second test layer 642 will not affect the work function properties of first test layer 632 as long as the thickness of first test layer 632 exceeds the saturation thickness, as noted above. Outside of first site isolated region 608a and second site isolated region 608b, second test layer 642 is separated from base layer 602 by a combination of blocking layer 634 and first test layer 632.

In an example embodiment, first test layer 632 and second test layer 642 have substantially the same composition. However, second test layer 642 may be deposited using a different deposition technique than first test layer 632. For example, first test layer 632 may be deposited using a CVD technique, while second test layer 642 may be deposited using an ALD technique. This approach may be used to test effects of deposition techniques on work function properties of different materials.

In another example embodiment, first test layer 632 and second test layer 642 may have different compositions. Second test layer 642 may be deposited using the same deposition technique as first test layer 632 or, alternatively, a different deposition technique than the one used for the first test layer.

Returning to FIG. 5, in some embodiments, additional test samples may be formed as illustrated by decision block 514. The additional test samples may be formed by selective removal of a third portion of the blocking layer, a second portion of the first test layer, and a first portion of the second test layer in a third site isolated region of the multiple site isolated regions. Thereby, a third exposed portion of the base layer may be created.

A third test layer may be deposited over the second test layer and the third exposed portion of the base layer. A thickness of the third test layer may be between about 1 nanometer and 20 nanometers, but may exceed the saturated thickness of the layer material.

FIG. 6F shows a substrate portion 650 in which third test layer 652 is deposited over second test layer 642. The third test layer may be deposited using such deposition techniques as ALD, CVD, PVD, and so forth, mentioned above with regard to the deposition of the first test layer. Third test layer 652 is separated from base layer 602 in both first site isolated regions 608a and second site isolated region 608b. Specifically, in first site isolated region 608a, third test layer 652 is separated from base layer by first layer 632 and second layer 642. Regardless of presence of third test layer 652 and second test layer 642 in this site isolated region 608a, the work function properties of this stack in that region will be determined by first test layer 632. In second site isolated region 608b, third test layer 652 is separated from base layer by second layer 642 only. Again, despite the presence of overlying third test layer 652 in second site isolated region 608b, the work function properties of this stack in that region will be determined by second test layer 642.

In an example embodiment, the third test layer and the second test layer may have the same composition. In this specific embodiment, the third test layer may be deposited using a different deposition technique than the one used for the second test layer. In particular, the second test layer may be deposited using the CVD techniques, and the third test layer may be deposited using the ALD technique.

In another example embodiment, the second test layer and the third test layer may have different compositions. In this specific embodiment, the third test layer may be deposited using the same deposition technique as the one used for the second test layer or, alternatively, a different deposition technique than the one used for the second test layer.

To uncover the base layer in the third site-isolated region, the third portion of the blocking layer, the second portion of the first test layer, and the first portion of the second test layer may be etched using different etching conditions. The selective removal of the portion of the blocking layer, the portion of the first test layer, and the first portion of the second test layer in the third site isolated region may include selective removal of the portion of the blocking layer using a first set of process conditions, selective removal of the portion of the first test layer using a second set of process conditions, and selective removal of the portion of the second test layer using a third set of process conditions. All three sets of process conditions may differ from each other. For example, the portion of the blocking layer may be sealed using a first cell containing one etching solution, while the first test layer may be sealed using a second cell containing another etching solution, and while the second test layer may be sealed using a third cell containing yet another etching solution. These different process conditions may be provided by specific configurations of the processing equipment as described above with reference to FIG. 4. The blocking layer may be non-resistant to the etching solutions used for the third set of process conditions but resistant to the etching solution used for the second set of process conditions.

In an example embodiment, a first set of process conditions is used for removal of the portion of the second test layer and the portion of the first test layer, and a second set of process conditions is used for removal of the portion of the blocking layer. The blocking layer may be non-resistant to etching solutions used for the second set of process conditions but resistant to an etching solution used for the first set of process conditions.

In another example embodiment, the third portion of the blocking layer, the second portion of the first test layer, and the first portion of the second test layer may be etched using the same process conditions. In this embodiment, the base layer may be resistant to an etching solution used for the process conditions.

Returning to FIG. 5, method 500 may proceed with measuring one or more work function properties of the first site isolated region, the second site isolated region, and any other site isolated regions that may be available on the substrate and ready for testing in operation 516. The measuring may include one of a capacitance test, a resistance test, or a transistor test. As a result of the test, a capacitance-voltage curve (CV-curve) or a current-voltage curve (IV-curve) may be obtained for each test layer for different site isolated regions. The CV-curve and IV-curve may be used to determine characteristics of the test layers by appropriate methodologies, instrumentation, and software. In general, many techniques have been developed based on different physical effects to measure the work function of a sample. Typically, absolute experimental methods for work function measurements employ electron emission from the sample induced by photon absorption (photoemission), by high temperature (thermionic emission), due to an electric field (field electron emission), or using electron tunneling. Relative experimental methods for work function measurements make use of the contact potential difference between the sample and a reference electrode. Experimentally, either an anode current of a diode is used or the displacement current between the sample and reference, created by an artificial change in the capacitance between the two, is measured.

The measuring one or more work function properties in the first site isolated region may be sensitive only with regard to a “test layer—base layer” interface. The thickness of the first test layer may be sufficient to dominate the work function properties of the stack over the first test layer. In view of this, the work function properties of the first site isolated region may be not impacted by the presence of the second test layer and the third test layer in the first site isolated region. Similarly, the thickness of the second test layer may be sufficient to dominate the work function properties of the stack over the second test layer. Therefore, the work function properties of the second site isolated region may be not impacted by presence of the third test layer in the second site isolated region. In general, any number of site isolated regions may be present on the same substrate. Therefore, any number of test layers may be deposited and tested on the same substrate.

### CONCLUSION

Although the foregoing concepts have been described in some detail for purposes of clarity of understanding, it will be apparent that certain changes and modifications may be practiced within the scope of the appended claims. It should be noted that there are many alternative ways of implementing the processes, systems, and apparatuses. Accordingly, the present embodiments are to be considered as illustrative and not restrictive.

What is claimed is:

1. A method of high productivity combinatorial (HPC) testing of multiple work function materials on a semiconductor substrate, the method comprising:
providing the semiconductor substrate comprising a first layer,
the substrate having multiple site isolated regions;
depositing a second layer on the semiconductor substrate over the first layer;
selectively removing a first portion of the second layer in a first site isolated region of the multiple site isolated regions thereby creating a first exposed portion of the first layer;
depositing a first test layer over the second layer and the first exposed portion of the first layer,
the first test layer comprising a first work function material;
selectively removing a second portion of the second layer and a first portion of the first test layer in a second site isolated region of the multiple site isolated regions thereby creating a second exposed portion of the first layer;
depositing a second test layer over the first test layer and the second exposed portion of the first layer; and
measuring one or more work function properties in the first site isolated region and the second site isolated region of the substrate.

2. The method of claim 1, wherein the first layer comprises a dielectric material, the dielectric material comprising one of silicon oxide, aluminum oxide, hafnium oxide, zirconium oxide, or a combination thereof.

3. The method of claim 1, wherein the second layer comprises one of silicon, silicon nitride, titanium nitride, tantalum nitride, or silicon oxide.

4. The method of claim 1, wherein the first layer remains substantially intact when selectively removing the first portion of the second layer in the first site isolated region and when selectively removing the portion of the second layer and the portion of the first test layer in the second site isolated region.

5. The method of claim 1, wherein selectively removing the portion of the second layer and the portion of the first test layer in the second site isolated region comprises: selectively removing the portion of the second layer using a first set of process conditions; and selectively removing the portion of the first test layer using a second set of process conditions different from the first set of process conditions.

6. The method of claim 5, wherein selectively removing the portion of the first test layer comprises contacting the first test layer in the second site isolated region with a first etching solution thereby forming an exposed portion of the second layer, and wherein selectively removing the portion of the second layer comprises contacting the exposed portion of the second layer with a second etching solution, the second etching solution having a different composition than the first etching solution.

7. The method of claim 6, wherein the first layer is not resistant to the first etching solution.

8. The method of claim 1, wherein selectively removing the portion of the second layer and the portion of the first test layer in the second site isolated region is performed in one operation using a same set of process conditions.

9. The method of claim 8, wherein selectively removing the portion of the second layer and the portion of the first test layer in the second site isolated region comprises contacting the first test layer and the second layer with an etching solution.

10. The method of claim 9, wherein the first layer is resistant to the etching solution.

11. The method of claim 1, wherein selectively removing the portion of the second layer and the portion of the first test layer in the second site isolated region is performed by contacting the second site isolated region with one or more etching solutions such that a remaining portion of the semiconductor substrate outside of the second site isolated region does not come in contact with the one or more etching solutions.

12. The method of claim 1, further comprising, prior to measuring,
selectively removing a third portion of the second layer, a second portion of the first test layer, and a first portion of the second test layer in a third site isolated region of the multiple site isolated regions thereby creating a third exposed portion of the first layer; and
depositing a third test layer over the second test layer and the third exposed portion of the first layer.

13. The method of claim 1, wherein depositing the first test layer and the second test layer comprises one or more of an atomic layer deposition (ALD) technique, a chemical vapor deposition (CVD) technique, or a physical vapor deposition (PVD) technique.

14. The method of claim 13, wherein the first test layer is deposited using a different technique than the second test layer.

15. The method of claim 14, wherein the first test layer and the second test layer have the same composition.

16. The method of claim 14, wherein the first test layer is deposited using the CVD technique and the second test layer is deposited using the ALD technique.

17. The method of claim 1, wherein the second test layer is deposited over the first test layer in the first site isolated region.

18. The method of claim 1, wherein a thickness of each of the first test layer and the second test layer is between about 1 nanometer and 20 nanometers.

19. The method of claim 1, wherein testing the first site isolated region and the second site isolated region of the substrate comprises one of a capacitance test, a resistance test, or a transistor test.

20. The method of claim 1, wherein the one or more work function properties of the first site isolated region are not impacted by a presence of the second test layer in the first site isolated region.
